(19) United States
(12) Patent Application Publication
(10) Pub. No.: US 2021/0360791 A1
(43) Pub. Date: Nov. 18, 2021

(54) IMAGE DISPLAY AND CIRCUIT CARRYING AND CONTROLLING MODULE THEREOF

(71) Applicant: ASTI GLOBAL INC., TAIWAN, Taichung City (TW)

(72) Inventor: CHIEN-SHOU LIAO, New Taipei City (TW)

(21) Appl. No.: 17/316,941

(22) Filed: May 11, 2021

(30) Foreign Application Priority Data
May 12, 2020 (TW) 109115666

(51) Int. Cl. H05K 1/18; G06F 1/18

(52) U.S. Cl. CPC H05K 1/181; H05K 2201/10128; G06F 1/189

(57) ABSTRACT

An image display and a circuit carrying and controlling module thereof are provided. The circuit carrying and controlling module includes a circuit substrate structure and a control substrate structure. The circuit substrate structure includes a carrier substrate, a circuit layout layer disposed on the carrier substrate, and a plurality of conductive penetration bodies that electrically connect to the circuit layout layer and penetrate through the carrier substrate. The control substrate structure includes a circuit substrate disposed under the circuit substrate structure, and a circuit control chip disposed on the circuit substrate. The control substrate structure can be disposed under the circuit substrate structure, and the control substrate structure can be electrically connected to the circuit substrate structure through the conductive penetration bodies.

### CROSS-REFERENCE TO RELATED PATENT APPLICATION

This application claims the benefit of priority to Taiwan Patent Application No. 109115666, filed on May 12, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a display and a carrying and controlling module thereof, and more particularly to an image display and a circuit carrying and controlling module thereof.

### BACKGROUND OF THE DISCLOSURE

In the related art, a width-wise space of an image display is partially occupied by a flexible printed circuit board that is provided with a circuit control chip.

### SUMMARY OF THE DISCLOSURE

In response to the above-referenced technical inadequacy, the present disclosure provides an image display and a circuit carrying and controlling module thereof.

In one aspect, the present disclosure provides a circuit carrying and controlling module including a circuit substrate structure and a control substrate structure. The circuit substrate structure includes a carrier substrate, a circuit layout layer disposed on the carrier substrate, and a plurality of conductive penetration bodies that electrically connect to the circuit layout layer and penetrate through the carrier substrate. The control substrate structure includes a circuit substrate disposed under the circuit substrate structure, and a circuit control chip disposed on the circuit substrate.

In another aspect, the present disclosure provides a circuit carrying and controlling module including a first circuit substrate structure, a first control substrate structure, a second circuit substrate structure, and a second control substrate structure. The first circuit substrate structure includes a first carrier substrate, a first circuit layout layer disposed on a top surface of the first carrier substrate, and a plurality of first conductive penetration bodies that electrically connect to the first circuit layout layer and penetrate through the first carrier substrate. The first control substrate structure includes a first circuit substrate disposed under a bottom surface of the first carrier substrate, and a first circuit control chip disposed on the first circuit substrate. The second circuit substrate structure includes a second carrier substrate, a second circuit layout layer disposed on a top surface of the second carrier substrate, and a plurality of second conductive penetration bodies that electrically connect to the second circuit layout layer and penetrate through the second carrier substrate. The second control substrate structure includes a second circuit substrate disposed under a bottom surface of the second carrier substrate, and a second circuit control chip disposed on the second circuit substrate. The first circuit substrate structure and the first control substrate structure are disposed inside a casing, and a first lateral side of the first carrier substrate is adjacent to or in contact with a first inner surface of the casing, so that a first unoccupied gap is formed between the first lateral side of the first carrier substrate and the first inner surface of the casing. The second circuit substrate structure and the second control substrate structure are disposed inside a casing, and a first lateral side of the second carrier substrate is adjacent to or in contact with a second inner surface of the casing, so that a second unoccupied gap is formed between the first lateral side of the second carrier substrate and the second inner surface of the casing. A second lateral side of the first carrier substrate is adjacent to or in contact with a second lateral side of the second carrier substrate, so that a third unoccupied gap is formed between the second lateral side of the first carrier substrate and the second lateral side of the second carrier substrate.

In yet another aspect, the present disclosure provides an image display including a circuit carrying and controlling module and an image display module that is electrically connected to the circuit carrying and controlling module. The circuit carrying and controlling module includes a circuit substrate structure and a control substrate structure. The circuit substrate structure includes a carrier substrate, a circuit layout layer disposed on the carrier substrate, and a plurality of conductive penetration bodies that electrically connect to the circuit layout layer and penetrate through the carrier substrate. The control substrate structure includes a circuit substrate disposed under the circuit substrate structure, and a circuit control chip disposed on the circuit substrate. The image display module is electrically connected to the circuit layout layer of the circuit substrate structure.

Therefore, by virtue of “the circuit substrate structure including a carrier substrate, a circuit layout layer disposed on the carrier substrate, and a plurality of conductive penetration bodies electrically connected to the circuit layout layer and penetrating through the carrier substrate” and “the control substrate structure including a circuit substrate disposed under the circuit substrate structure, and a circuit control chip disposed on the circuit substrate”, the control substrate structure can be disposed under the circuit substrate structure, and the control substrate structure can be electrically connected to the circuit substrate structure through the conductive penetration bodies.

These and other aspects of the present disclosure will become apparent from the following description of the embodiment taken in conjunction with the following drawings and their captions, although variations and modifications therein can be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a circuit carrying and controlling module disposed inside a casing according to a first embodiment of the present disclosure;

FIG. 2 shows a schematic enlarged view of part II of FIG. 1;

FIG. 3 is a partial schematic top view of the circuit carrying and controlling module according to the first embodiment of the present disclosure;

FIG. 4 is a schematic bottom view of the circuit carrying and controlling module according to the first embodiment of the present disclosure;

FIG. 5 is a schematic cross-sectional view of a circuit carrying and controlling module disposed inside a casing according to a second embodiment of the present disclosure;

FIG. 6 shows a schematic enlarged view of part VI of FIG. 5;

FIG. 7 is a partial schematic top view of the circuit carrying and controlling module according to the second embodiment of the present disclosure;

FIG. 8 is a schematic bottom view of the circuit carrying and controlling module according to the second embodiment of the present disclosure;

FIG. 9 is a schematic cross-sectional view of a circuit carrying and controlling module disposed inside a casing according to a third embodiment of the present disclosure;

FIG. 10 is a schematic cross-sectional view of an image display according to a fourth embodiment of the present disclosure;

FIG. 11 is a schematic cross-sectional view of an image display according to a fifth embodiment of the present disclosure;

FIG. 12 is a schematic cross-sectional view of another image display according to the fifth embodiment of the present disclosure;

FIG. 13 is a schematic cross-sectional view of an image display according to a sixth embodiment of the present disclosure;

FIG. 14 is a schematic cross-sectional view of an image display according to a seventh embodiment of the present disclosure; and

FIG. 15 is a schematic cross-sectional view of another image display according to the seventh embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

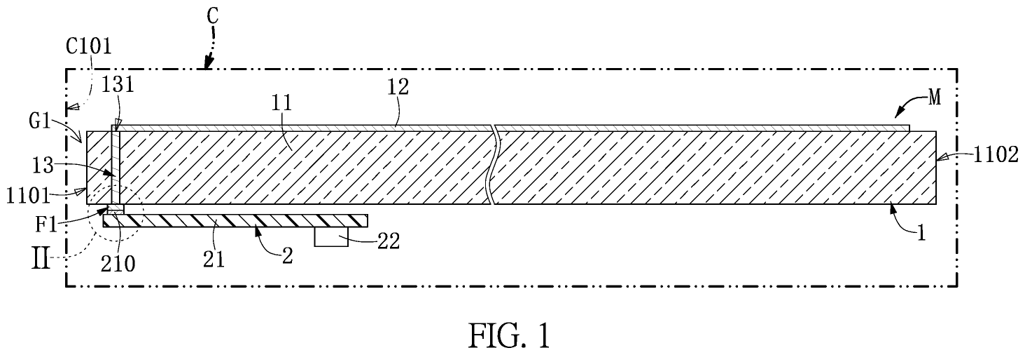

Referring to FIG. 1 to FIG. 4, a first embodiment of the present disclosure provides a circuit carrying and controlling module M including a first circuit substrate structure 1 (i.e., a circuit substrate structure) and a first control substrate structure 2 (i.e., a control substrate structure).

More particularly, referring to FIG. 1 to FIG. 3, the first circuit substrate structure 1 includes a first carrier substrate 11 (i.e., a carrier substrate), a first circuit layout layer 12 (i.e., a circuit layout layer) disposed on a top surface of the first carrier substrate 11, and a plurality of first conductive penetration bodies 13 (i.e., a plurality of conductive penetration bodies) that electrically connect to the first circuit layout layer 12 and penetrate through the first carrier substrate 11. In addition, each of the first conductive penetration bodies 13 includes a first top soldering region 131 (i.e., a top soldering region) and a first bottom soldering region 132 (i.e., a bottom soldering region) corresponding to the first top soldering region 131, and the first top soldering region 131 and the first bottom soldering region 132 are respectively disposed on two opposite ends of the first conductive penetration body 13. For example, the first carrier substrate 11 can be a silicon substrate, a glass substrate, or any kind of circuit carrier substrate for carrying a circuit layer. However, the aforementioned description is merely an example and is not meant to limit the scope of the present disclosure.

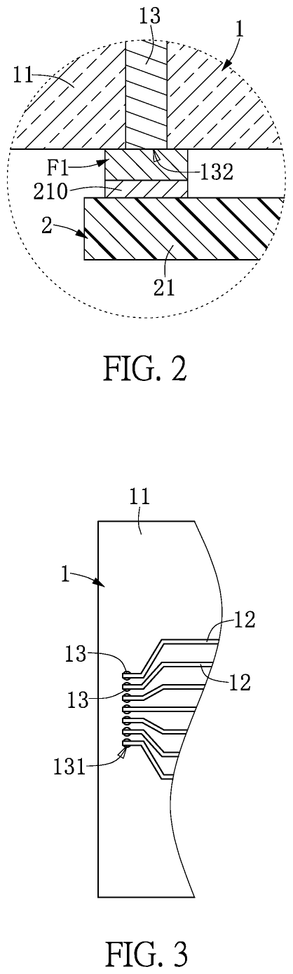

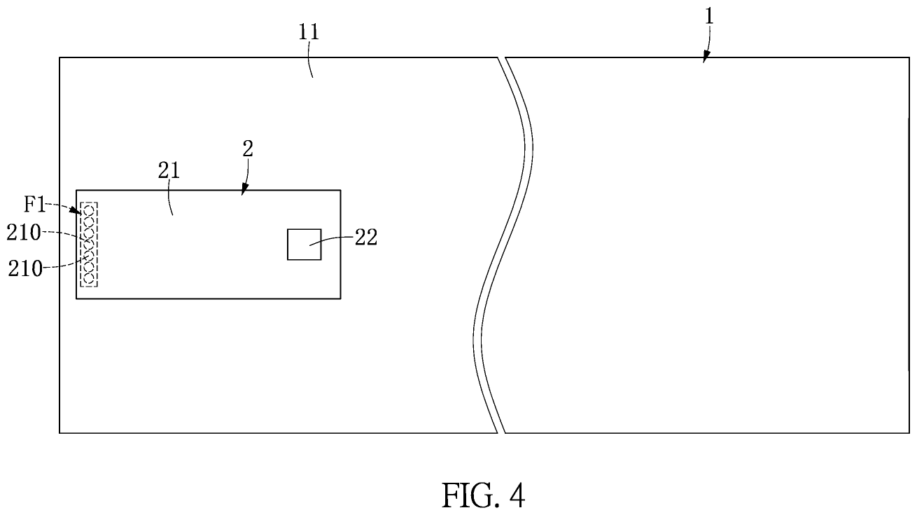

More particularly, referring to FIG. 1, FIG. 2 and FIG. 4, the first control substrate structure 2 includes a first circuit substrate 21 (i.e., a circuit substrate) disposed under a bottom surface of the first carrier substrate 11, and a first circuit control chip 22 (i.e., a circuit control chip, or a signal control chip) disposed on the first circuit substrate 21, and the first circuit control chip 22 is electrically connected to the first circuit substrate 21. In addition, the first circuit layout layer 12 and the first circuit substrate 21 can respectively and electrically connect to the first top soldering region 131 and the first bottom soldering region 132. For example, the first circuit substrate 21 can be a rigid circuit board or a flexible circuit board, and the first circuit substrate 21 includes a plurality of first conductive contacts 210 (i.e., a plurality of conductive contacts) that are respectively and electrically connected to the first conductive penetration bodies 13. Moreover, the first conductive contacts 210 of the first circuit substrate 21 can respectively and electrically connect to the first bottom soldering regions 132 of the first conductive penetration bodies 13 through a first anisotropic conduction film F1 (i.e., an anisotropic conduction film), and the first anisotropic conduction film F1 can be replaced with anisotropic conductive glue, a cable connector or a plurality of solder balls. However, the aforementioned description is merely an example and is not meant to limit the scope of the present disclosure.

It should be noted that as shown in FIG. 1, when the first circuit substrate structure 1 and the first control substrate structure 2 are disposed inside a casing C, a first lateral side 1101 of the first carrier substrate 11 can be adjacent (or proximate) to or in contact with (such as in direct or indirect contact with) a first inner surface C101 of the casing C, so that a first unoccupied gap G1 (i.e., an unoccupied gap) is formed between the first lateral side 1101 of the first carrier substrate 11 and the first inner surface C101 of the casing C. Furthermore, the first control substrate structure 2 can be placed under the first circuit substrate structure 1, and the first control substrate structure 2 can be electrically connected to the first circuit layout layer 12 of the first circuit substrate structure 1 through the first conductive penetration bodies 13, so that the first control substrate structure 2 can be electrically connected to the first circuit layout layer 12 of the first circuit substrate structure 1 without passing through (extending across) the first unoccupied gap G1. As a result, a distance or a space between the first lateral side 1101 of the first carrier substrate 11 and the first inner surface C101 of the casing C can be effectively reduced, thus allowing a size (or a width) of the casing C of an electronic product using the circuit carrying and controlling module M to be effectively reduced.

### Second Embodiment

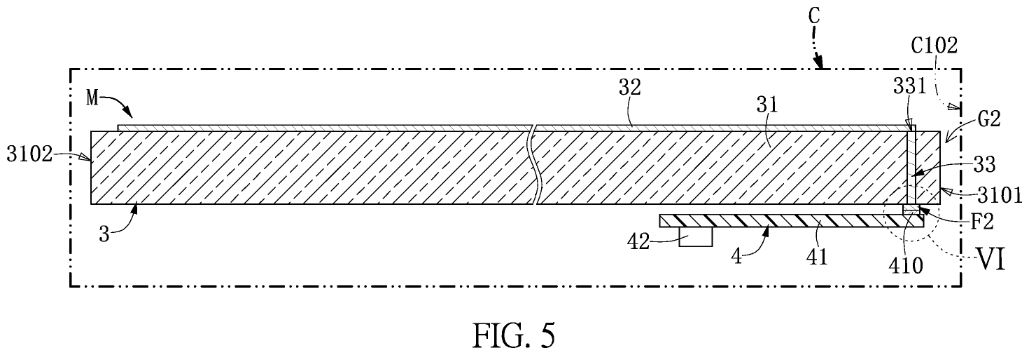

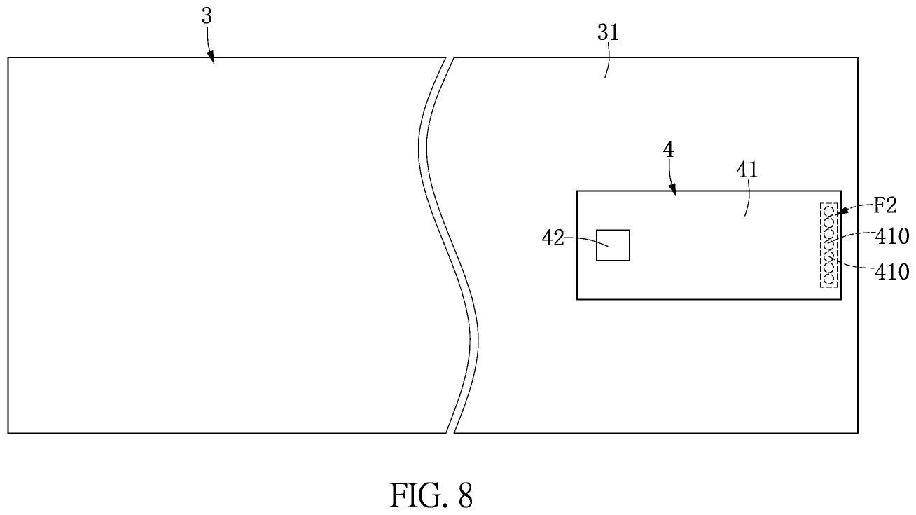

Referring to FIG. 5 to FIG. 8, a second embodiment of the present disclosure provides a circuit carrying and controlling module M including a second circuit substrate structure 3 (i.e., another circuit substrate structure) and a second control substrate structure 4 (i.e., another control substrate structure).

More particularly, referring to FIG. 5 to FIG. 7, the second circuit substrate structure 3 includes a second carrier substrate 31 (i.e., another carrier substrate), a second circuit layout layer 32 (i.e., another circuit layout layer) disposed on a top surface of the second carrier substrate 31, and a plurality of second conductive penetration bodies 33 (i.e., another plurality of conductive penetration bodies) that electrically connect to the second circuit layout layer 32 and penetrate through the second carrier substrate 31. In addition, each of the second conductive penetration bodies 33 includes a second top soldering region 331 (i.e., another top soldering region) and a second bottom soldering region 332 (i.e., another bottom soldering region) corresponding to the second top soldering region 331, and the second top soldering region 331 and the second bottom soldering region 332 are respectively disposed on two opposite ends of the second conductive penetration body 33. For example, the second carrier substrate 31 can be a silicon substrate, a glass substrate, or any kind of circuit carrier substrate for carrying a circuit layer. However, the aforementioned description is merely an example and is not meant to limit the scope of the present disclosure.

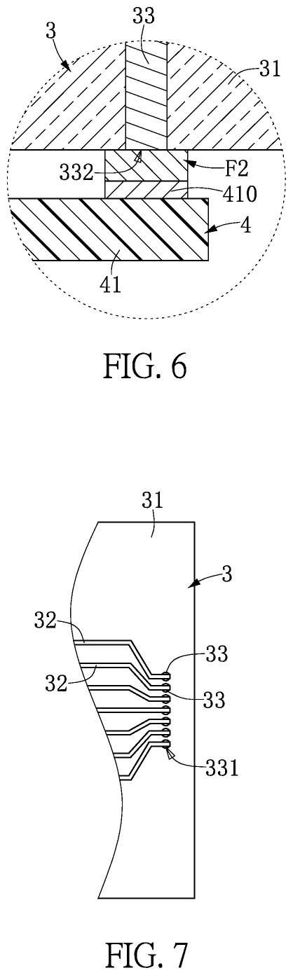

More particularly, referring to FIG. 5, FIG. 6 and FIG. 8, the second control substrate structure 4 includes a second circuit substrate 41 (i.e., another circuit substrate) disposed under a bottom surface of the second carrier substrate 31, and a second circuit control chip 42 (i.e., another circuit control chip, or a signal control chip) disposed on the second circuit substrate 41, and the second circuit control chip 42 is electrically connected to the second circuit substrate 41. In addition, the second circuit layout layer 32 and the second circuit substrate 41 can respectively and electrically connect to the second top soldering region 331 and the second bottom soldering region 332. For example, the second circuit substrate 41 can be a rigid circuit board or a flexible circuit board, and the second circuit substrate 41 includes a plurality of second conductive contacts 410 (i.e., another plurality of conductive contacts) that are respectively and electrically connected to the second conductive penetration bodies 33. Moreover, the second conductive contacts 410 of the second circuit substrate 41 can respectively and electrically connect to the second bottom soldering regions 332 of the second conductive penetration bodies 33 through a second anisotropic conduction film F2 (i.e., another anisotropic conduction film), and the second anisotropic conduction film F2 can be replaced with anisotropic conductive glue, a cable connector or a plurality of solder balls. However, the aforementioned description is merely an example and is not meant to limit the scope of the present disclosure.

It should be noted that as shown in FIG. 5, when the second circuit substrate structure 3 and the second control substrate structure 4 are disposed inside a casing C, a first lateral side 3101 of the second carrier substrate 31 can be adjacent (or proximate) to or in contact with (such as in direct or indirect contact with) a second inner surface C102 of the casing C, so that a second unoccupied gap G2 (i.e., another unoccupied gap) is formed between the first lateral side 3101 of the second carrier substrate 31 and the second inner surface C102 of the casing C. Furthermore, the second control substrate structure 4 can be placed under the second circuit substrate structure 3, and the second control substrate structure 4 can be electrically connected to the second circuit layout layer 32 of the second circuit substrate structure 3 through the second conductive penetration bodies 33, so that the second control substrate structure 4 can be electrically connected to the second circuit layout layer 32 of the second circuit substrate structure 3 without passing through (extending across) the second unoccupied gap G2. As a result, a distance or a space between the first lateral side 3101 of the second carrier substrate 31 and the second inner surface C102 of the casing C can be effectively reduced, thus allowing a size (or a width) of the casing C of an electronic product using the circuit carrying and controlling module M to be effectively reduced.

### Third Embodiment

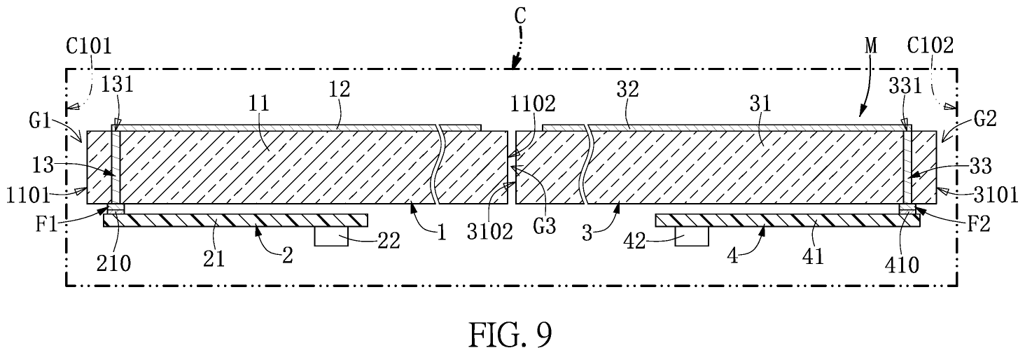

Referring to FIG. 9, a third embodiment of the present disclosure provides a circuit carrying and controlling module M including a first circuit substrate structure 1, a first control substrate structure 2, a second circuit substrate structure 3, and a second control substrate structure 4. Comparing FIG. 9 with FIG. 1 and FIG. 5, the biggest difference between the third embodiment and the first and the second embodiments is as follows: in the third embodiment, a second lateral side 1102 of the first carrier substrate 11 can be adjacent (or proximate) to or in contact with (such as in direct or indirect contact with) a second lateral side 3102 of the second carrier substrate 31, so that a third unoccupied gap G3 (i.e., yet another unoccupied gap) is formed between the second lateral side 1102 of the first carrier substrate 11 and the second lateral side 3102 of the second carrier substrate 31.

It should be noted that as shown in FIG. 9, the first control substrate structure 2 can be placed under the first circuit substrate structure 1, and the first control substrate structure 2 can be electrically connected to the first circuit layout layer 12 of the first circuit substrate structure 1 through the first conductive penetration bodies 13, so that the first control substrate structure 2 can be electrically connected to the first circuit layout layer 12 of the first circuit substrate structure 1 without passing through (extending across) the first unoccupied gap G1 or the third unoccupied gap G3. As a result, a distance or a space between the first lateral side 1101 of the first carrier substrate 11 and the first inner surface C101 of the casing C can be effectively reduced, and a distance or a space between the second lateral side 1102 of the first carrier substrate 11 and the second lateral side 3102 of the second carrier substrate 31 can be effectively reduced, thus allowing a size (or a width) of the casing C of an electronic product using the circuit carrying and controlling module M to be effectively reduced.

It should be noted that as shown in FIG. 9, the second control substrate structure 4 can be placed under the second circuit substrate structure 3, and the second control substrate structure 4 can be electrically connected to the second circuit layout layer 32 of the second circuit substrate structure 3 through the second conductive penetration bodies 33, so that the second control substrate structure 4 can be electrically connected to the second circuit layout layer 32 of the second circuit substrate structure 3 without passing through (extending across) the second unoccupied gap G2 or the third unoccupied gap G3. As a result, a distance or a space between the first lateral side 3101 of the second carrier substrate 31 and the second inner surface C102 of the casing C can be effectively reduced, and a distance or a space between the second lateral side 1102 of the first carrier substrate 11 and the second lateral side 3102 of the second carrier substrate 31 can be effectively reduced, thus allowing a size (or a width) of the casing C of an electronic product using the circuit carrying and controlling module M to be effectively reduced.

### Fourth Embodiment

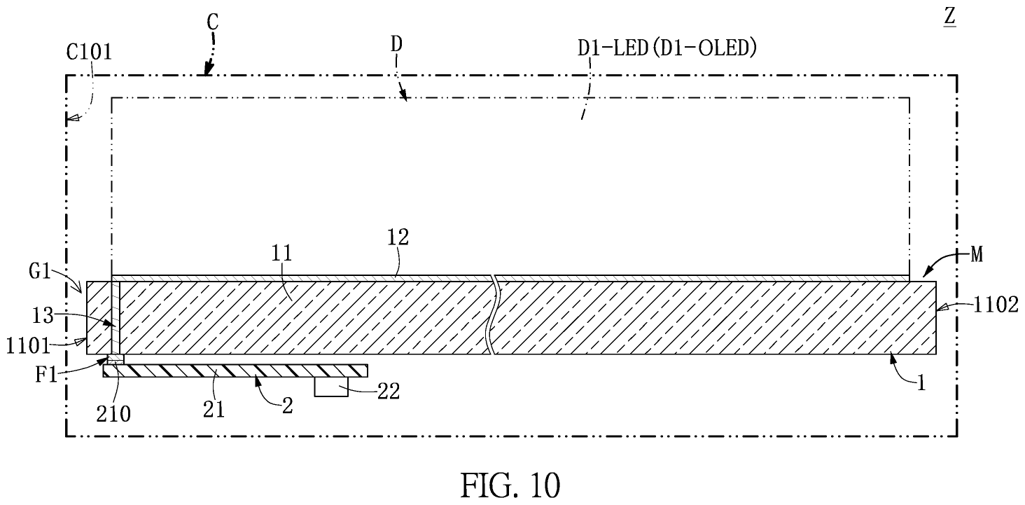

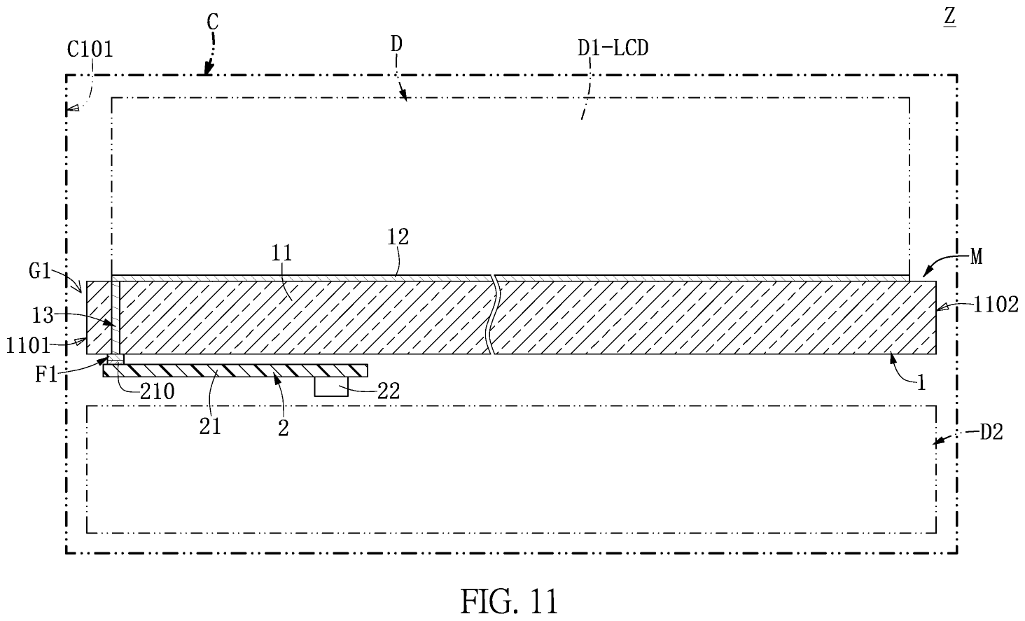

Referring to FIG. 1 and FIG. 10, a fourth embodiment of the present disclosure provides an image display Z including a circuit carrying and controlling module M and an image display module D that is electrically connected to the circuit carrying and controlling module M. In addition, the circuit carrying and controlling module M includes a first circuit substrate structure 1 and a first control substrate structure 2 (which have the same configuration as that in the first embodiment, as shown in FIG. 1), and the image display module D is electrically connected to the first circuit layout layer 12 of the first circuit substrate structure 1. For example, the image display module D can be an LED (light-emitting diode) display module (D1-LED) or an OLED (organic light-emitting diode) display module (D1-OLED) that is disposed above the circuit carrying and controlling module M. However, the aforementioned description is merely an example and is not meant to limit the scope of the present disclosure.

Therefore, the first control substrate structure 2 can be electrically connected to the first circuit layout layer 12 of the first circuit substrate structure 1 without passing through (extending across) the first unoccupied gap G1, so that the distance or the space between the first lateral side 1101 of the first carrier substrate 11 and the first inner surface C101 of the casing C can be effectively reduced, thus allowing the size (or the width) of the casing C of the image display Z using the circuit carrying and controlling module M to be effectively reduced.

### Fifth Embodiment

Referring to FIG. 1 and FIG. 11, a fifth embodiment of the present disclosure provides an image display Z including a circuit carrying and controlling module M and an image display module D that is electrically connected to the circuit carrying and controlling module M. In addition, the circuit carrying and controlling module M includes a first circuit substrate structure 1 and a first control substrate structure 2 (which have the same configuration as that in the first embodiment, as shown in FIG. 1), and the image display module D is electrically connected to the first circuit layout layer 12 of the first circuit substrate structure 1. For example, the image display module D can be an LCD (light crystal display) module (D1-LCD) disposed above the circuit carrying and controlling module M for cooperating with a backlight module D2 that is disposed under the circuit carrying and controlling module M. However, the aforementioned description is merely an example and is not meant to limit the scope of the present disclosure.

Therefore, the first control substrate structure 2 can be electrically connected to the first circuit layout layer 12 of the first circuit substrate structure 1 without passing through (extending across) the first unoccupied gap G1, so that the distance or the space between the first lateral side 1101 of the first carrier substrate 11 and the first inner surface C101 of the casing C can be effectively reduced, thus allowing the size (or the width) of the casing C of the image display Z using the circuit carrying and controlling module M to be effectively reduced.

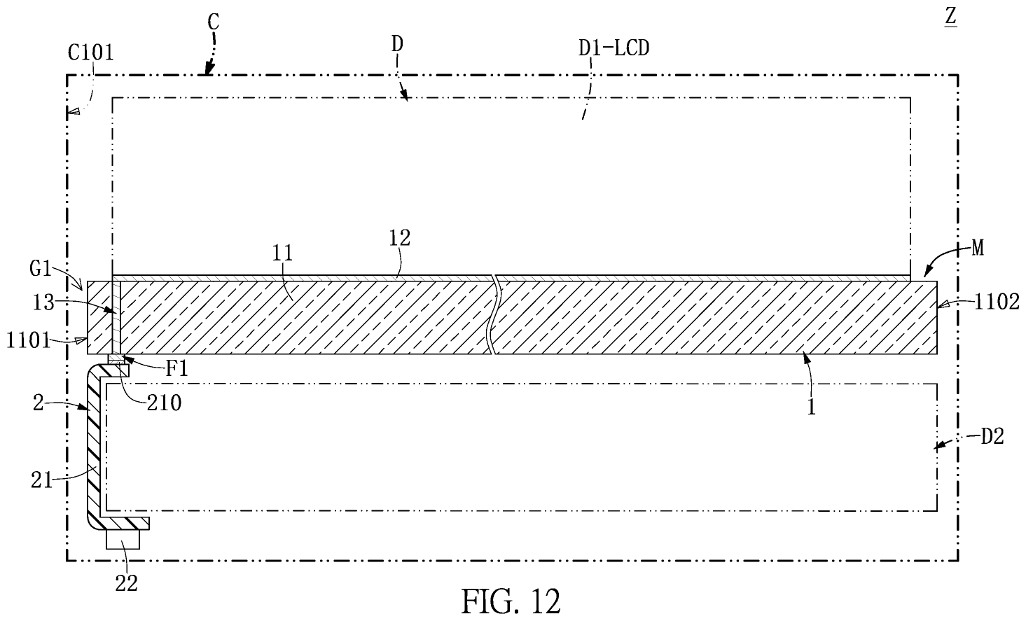

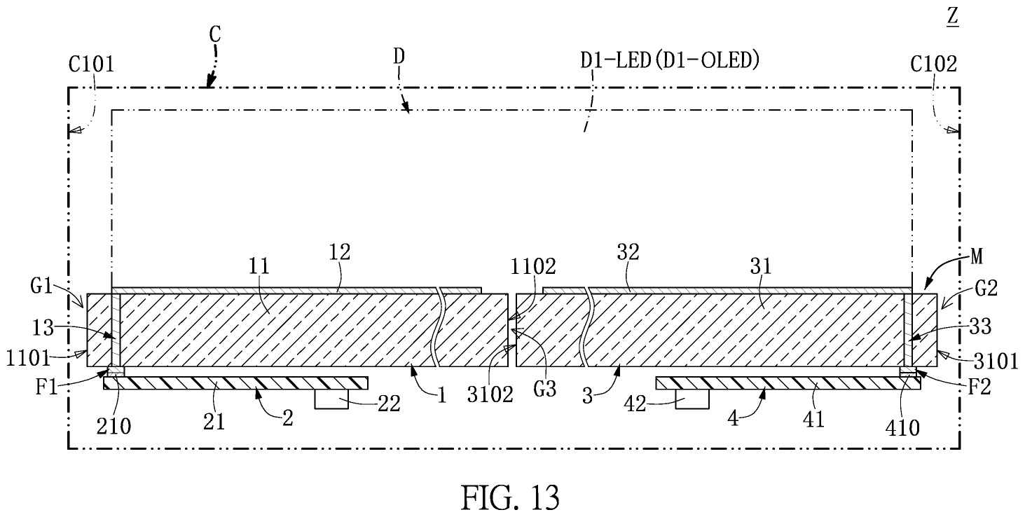

It should be noted that as shown in FIG. 12, the first control substrate structure 2 can be designed to extend along a side and a bottom surface of the backlight module D2 (that is to say, the first control substrate structure 2 does not need to be disposed between the first circuit substrate structure 1 and the backlight module D2), and the first circuit control chip 22 of the first control substrate structure 2 can be disposed under the backlight module D2. However, the aforementioned description is merely an example and is not meant to limit the scope of the present disclosure.

### Sixth Embodiment

Referring to FIG. 9 and FIG. 13, a sixth embodiment of the present disclosure provides an image display Z including a circuit carrying and controlling module M and an image display module D that is electrically connected to the circuit carrying and controlling module M. In addition, the circuit carrying and controlling module M includes a first circuit substrate structure 1, a first control substrate structure 2, a second circuit substrate structure 3, and a second control substrate structure 4 (which have the same configuration as that in the third embodiment, as shown in FIG. 9), and the image display module D is electrically connected to the first circuit layout layer 12 of the first circuit substrate structure 1 and the second layout layer 32 of the second circuit substrate structure 3. For example, the image display module D can be an LED (light-emitting diode) display module (D1-LED) or an OLED (organic light-emitting diode) display module (D1-OLED) that is disposed above the circuit carrying and controlling module M. However, the aforementioned description is merely an example and is not meant to limit the scope of the present disclosure.

Therefore, the first control substrate structure 2 can be electrically connected to the first circuit layout layer 12 of the first circuit substrate structure 1 through the first conductive penetration bodies 13, so that the first control substrate structure 2 can be electrically connected to the first circuit layout layer 12 of the first circuit substrate structure 1 without passing through (extending across) the first unoccupied gap G1 or the third unoccupied gap G3. As a result, a distance or a space between the first lateral side 1101 of the first carrier substrate 11 and the first inner surface C101 of the casing C can be effectively reduced, and a distance or a space between the second lateral side 1102 of the first carrier substrate 11 and the second lateral side 3102 of the second carrier substrate 31 can be effectively reduced, thus allowing a size (or a width) of the casing C of an electronic product using the circuit carrying and controlling module M to be effectively reduced.

Furthermore, the second control substrate structure 4 can be electrically connected to the second circuit layout layer 32 of the second circuit substrate structure 3 through the second conductive penetration bodies 33, so that the second control substrate structure 4 can be electrically connected to the second circuit layout layer 32 of the second circuit substrate structure 3 without passing through (extending across) the second unoccupied gap G2 or the third unoccupied gap G3. As a result, a distance or a space between the first lateral side 3101 of the second carrier substrate 31 and the second inner surface C102 of the casing C can be effectively reduced, and a distance or a space between the second lateral side 1102 of the first carrier substrate 11 and the second lateral side 3102 of the second carrier substrate 31 can be effectively reduced, thus allowing a size (or a width) of the casing C of an electronic product using the circuit carrying and controlling module M to be effectively reduced.

### Seventh Embodiment

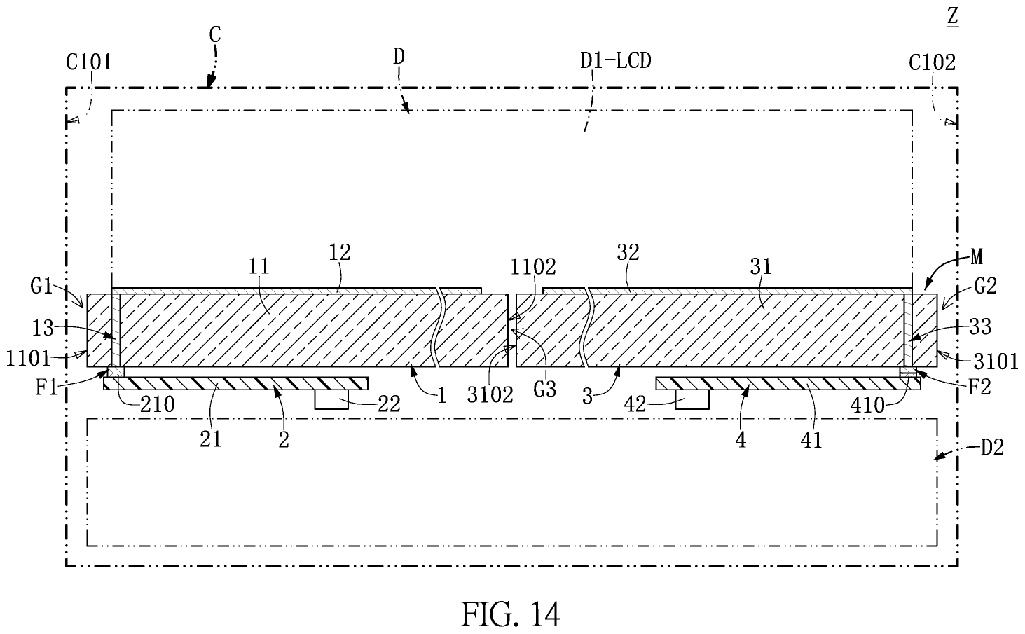

Referring to FIG. 9 and FIG. 14, a seventh embodiment of the present disclosure provides an image display Z including a circuit carrying and controlling module M and an image display module D that is electrically connected to the circuit carrying and controlling module M. In addition, the circuit carrying and controlling module M includes a first circuit substrate structure 1, a first control substrate structure 2, a second circuit substrate structure 3, and a second control substrate structure 4 (which have the same configuration as that in the third embodiment, as shown in FIG. 9), and the image display module D is electrically connected to the first circuit layout layer 12 of the first circuit substrate structure 1 and the second layout layer 32 of the second circuit substrate structure 3. For example, the image display module D can be an LCD (light crystal display) module (D1-LCD) disposed above the circuit carrying and controlling module M for cooperating with a backlight module D2 that is disposed under the circuit carrying and controlling module M. However, the aforementioned description is merely an example and is not meant to limit the scope of the present disclosure.

Therefore, the first control substrate structure 2 can be electrically connected to the first circuit layout layer 12 of the first circuit substrate structure 1 through the first conductive penetration bodies 13, so that the first control substrate structure 2 can be electrically connected to the first circuit layout layer 12 of the first circuit substrate structure 1 without passing through (extending across) the first unoccupied gap G1 or the third unoccupied gap G3. As a result, a distance or a space between the first lateral side 1101 of the first carrier substrate 11 and the first inner surface C101 of the casing C can be effectively reduced, and a distance or a space between the second lateral side 1102 of the first carrier substrate 11 and the second lateral side 3102 of the second carrier substrate 31 can be effectively reduced, thus allowing a size (or a width) of the casing C of an electronic product using the circuit carrying and controlling module M to be effectively reduced.

Furthermore, the second control substrate structure 4 can be electrically connected to the second circuit layout layer 32 of the second circuit substrate structure 3 through the second conductive penetration bodies 33, so that the second control substrate structure 4 can be electrically connected to the second circuit layout layer 32 of the second circuit substrate structure 3 without passing through (extending across) the second unoccupied gap G2 or the third unoccupied gap G3. As a result, a distance or a space between the first lateral side 3101 of the second carrier substrate 31 and the second inner surface C102 of the casing C can be effectively reduced, and a distance or a space between the second lateral side 1102 of the first carrier substrate 11 and the second lateral side 3102 of the second carrier substrate 31 can be effectively reduced, thus allowing a size (or a width) of the casing C of an electronic product using the circuit carrying and controlling module M to be effectively reduced.

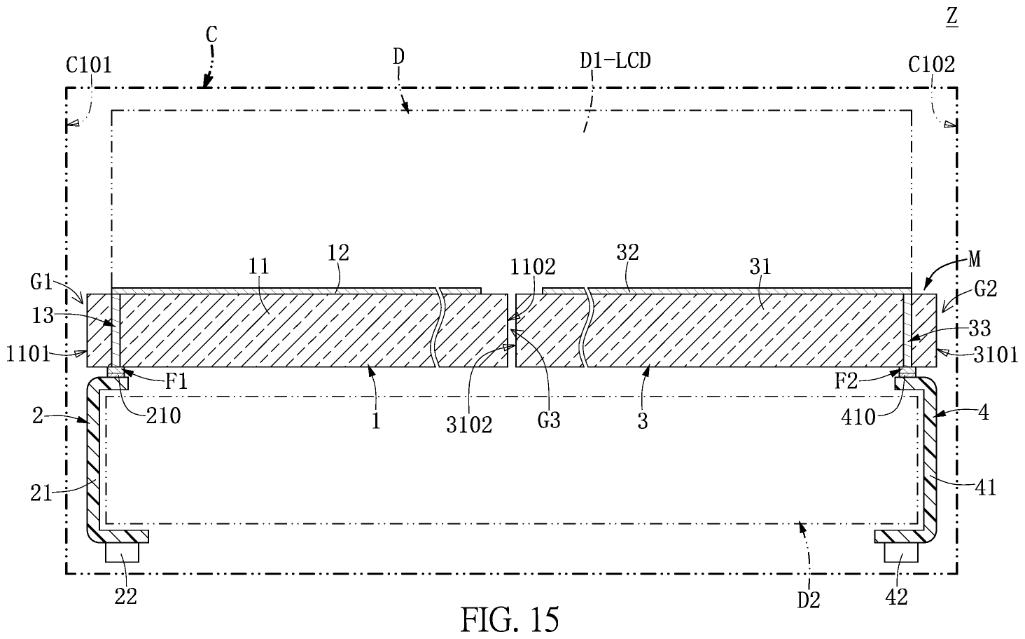

It should be noted that as shown in FIG. 15, the first control substrate structure 2 can be designed to extend along a side and a bottom surface of the backlight module D2 (that is to say, the first control substrate structure 2 does not need to be disposed between the first circuit substrate structure 1 and the backlight module D2), and the first circuit control chip 22 of the first control substrate structure 2 can be disposed under the backlight module D2. In addition, the second control substrate structure 4 can be designed to extend along another side and a bottom surface of the backlight module D2 (that is to say, the second control substrate structure 4 does not need to be disposed between the second circuit substrate structure 3 and the backlight module D2), and the second circuit control chip 42 of the second control substrate structure 4 can be disposed under the backlight module D2. However, the aforementioned description is merely an example and is not meant to limit the scope of the present disclosure.

### Beneficial Effects of the Embodiments

In conclusion, by virtue of “the circuit substrate structure including a carrier substrate, a circuit layout layer disposed on the carrier substrate, and a plurality of conductive penetration bodies electrically connected to the circuit layout layer and penetrating through the carrier substrate” and “the control substrate structure including a circuit substrate disposed under the circuit substrate structure, and a circuit control chip disposed on the circuit substrate”, the control substrate structure can be disposed under the circuit substrate structure, and the control substrate structure can be electrically connected to the circuit substrate structure through the conductive penetration bodies.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit carrying and controlling module, comprising:
a circuit substrate structure including a carrier substrate, a circuit layout layer disposed on the carrier substrate, and a plurality of conductive penetration bodies that electrically connect to the circuit layout layer and penetrate through the carrier substrate; and
a control substrate structure including a circuit substrate disposed under the circuit substrate structure, and a circuit control chip disposed on the circuit substrate.

2. The circuit carrying and controlling module according to claim 1, wherein the circuit substrate structure and the control substrate structure are disposed inside a casing, and a lateral side of the carrier substrate is adjacent to or in contact with an inner surface of the casing, so that an unoccupied gap is formed between the lateral side of the carrier substrate and the inner surface of the casing.

3. The circuit carrying and controlling module according to claim 2, wherein each of the conductive penetration bodies includes a top soldering region and a bottom soldering region corresponding to the top soldering region, and the circuit layout layer and the circuit substrate are respectively and electrically connected to the top soldering region and the bottom soldering region; wherein the circuit substrate includes a plurality of conductive contacts respectively and electrically connected to the conductive penetration bodies, and the conductive contacts of the circuit substrate are respectively and electrically connected to the bottom soldering regions of the conductive penetration bodies through an anisotropic conduction film;
wherein the circuit substrate is a rigid circuit board or a flexible circuit board, and the circuit substrate does not pass through the unoccupied gap.

4. The circuit carrying and controlling module according to claim 1, further comprising:
another circuit substrate structure including another carrier substrate, another circuit layout layer disposed on the another carrier substrate, and another plurality of conductive penetration bodies that electrically connect to the another circuit layout layer and penetrate through the another carrier substrate; and
another control substrate structure including another circuit substrate disposed under the another carrier substrate, and another circuit control chip disposed on the another circuit substrate.

5. The circuit carrying and controlling module according to claim 4, wherein the circuit substrate structure and the control substrate structure are disposed inside a casing, and a lateral side of the carrier substrate is adjacent to or in contact with an inner surface of the casing, so that an unoccupied gap is formed between the lateral side of the carrier substrate and the inner surface of the casing; wherein the another circuit substrate structure and the another control substrate structure are disposed inside the casing, and a lateral side of the another carrier substrate is adjacent to or in contact with another inner surface of the casing, so that another unoccupied gap is formed between the lateral side of the another carrier substrate and the another inner surface of the casing.

6. The circuit carrying and controlling module according to claim 5, wherein each of the another conductive penetration bodies includes another top soldering region and another bottom soldering region corresponding to the another top soldering region, and the another circuit layout layer and the another circuit substrate are respectively and electrically connected to the another top soldering region and the another bottom soldering region; wherein the another circuit substrate includes another plurality of conductive contacts respectively and electrically connected to the another conductive penetration bodies, and the another conductive contacts of the another circuit substrate are respectively and electrically connected to the another bottom soldering regions of the another conductive penetration bodies through another anisotropic conduction film; wherein the another circuit substrate is a rigid circuit board or a flexible circuit board, and the another circuit substrate does not pass through the another unoccupied gap.

7. A circuit carrying and controlling module, comprising:
a first circuit substrate structure including a first carrier substrate, a first circuit layout layer disposed on a top surface of the first carrier substrate, and a plurality of first conductive penetration bodies that electrically connect to the first circuit layout layer and penetrate through the first carrier substrate;
a first control substrate structure including a first circuit substrate disposed under a bottom surface of the first carrier substrate, and a first circuit control chip disposed on the first circuit substrate;
a second circuit substrate structure including a second carrier substrate, a second circuit layout layer disposed on a top surface of the second carrier substrate, and a plurality of second conductive penetration bodies that electrically connect to the second circuit layout layer and penetrate through the second carrier substrate;
a second control substrate structure including a second circuit substrate disposed under a bottom surface of the second carrier substrate, and a second circuit control chip disposed on the second circuit substrate;
wherein the first circuit substrate structure and the first control substrate structure are disposed inside a casing, and a first lateral side of the first carrier substrate is adjacent to or in contact with a first inner surface of the casing, so that a first unoccupied gap is formed between the first lateral side of the first carrier substrate and the first inner surface of the casing;
wherein the second circuit substrate structure and the second control substrate structure are disposed inside a casing, and a first lateral side of the second carrier substrate is adjacent to or in contact with a second inner surface of the casing, so that a second unoccupied gap is formed between the first lateral side of the second carrier substrate and the second inner surface of the casing;
wherein a second lateral side of the first carrier substrate is adjacent to or in contact with a second lateral side of the second carrier substrate, so that a third unoccupied gap is formed between the second lateral side of the first carrier substrate and the second lateral side of the second carrier substrate.

8. The circuit carrying and controlling module according to claim 7, wherein each of the first conductive penetration bodies includes a first top soldering region and a first bottom soldering region corresponding to the first top soldering region, and the first circuit layout layer and the first circuit substrate are respectively and electrically connected to the first top soldering region and the first bottom soldering region.

9. The circuit carrying and controlling module according to claim 7, wherein the first circuit substrate includes a plurality of first conductive contacts respectively and electrically connected to the first conductive penetration bodies, and the first conductive contacts of the first circuit substrate are respectively and electrically connected to the first bottom soldering regions of the first conductive penetration bodies through a first anisotropic conduction film; wherein the first circuit substrate is a rigid circuit board or a flexible circuit board, and the first circuit substrate does not pass through the first unoccupied gap.

10. The circuit carrying and controlling module according to claim 7, wherein each of the second conductive penetration bodies includes a second top soldering region and a second bottom soldering region corresponding to the second top soldering region, and the second circuit layout layer and the second circuit substrate are respectively and electrically connected to the second top soldering region and the second bottom soldering region.

11. The circuit carrying and controlling module according to claim 7, wherein the second circuit substrate includes a plurality of second conductive contacts respectively and electrically connected to the second conductive penetration bodies, and the second conductive contacts of the second circuit substrate are respectively and electrically connected to the second bottom soldering regions of the second conductive penetration bodies through a second anisotropic conduction film; wherein the second circuit substrate is a rigid circuit board or a flexible circuit board, and the second circuit substrate does not pass through the second unoccupied gap.

12. An image display comprising a circuit carrying and controlling module and an image display module that is electrically connected to the circuit carrying and controlling module, wherein the circuit carrying and controlling module includes:
a circuit substrate structure including a carrier substrate, a circuit layout layer disposed on the carrier substrate, and a plurality of conductive penetration bodies that electrically connect to the circuit layout layer and penetrate through the carrier substrate; and
a control substrate structure including a circuit substrate disposed under the circuit substrate structure, and a circuit control chip disposed on the circuit substrate;
wherein the image display module is electrically connected to the circuit layout layer of the circuit substrate structure.

13. The image display according to claim 12, wherein the circuit substrate structure and the control substrate structure are disposed inside a casing, and a lateral side of the carrier substrate is adjacent to or in contact with an inner surface of the casing, so that an unoccupied gap is formed between the lateral side of the carrier substrate and the inner surface of the casing.

14. The image display according to claim 13, wherein each of the conductive penetration bodies includes a top soldering region and a bottom soldering region corresponding to the top soldering region, and the circuit layout layer and the circuit substrate are respectively and electrically connected to the top soldering region and the bottom soldering region; wherein the circuit substrate includes a plurality of conductive contacts respectively and electrically connected to the conductive penetration bodies, and the conductive contacts of the circuit substrate are respectively and electrically connected to the bottom soldering regions of the conductive penetration bodies through an anisotropic conduction film; wherein the circuit substrate is a rigid circuit board or a flexible circuit board, and the circuit substrate does not pass through the unoccupied gap.

15. The image display according to claim 12, wherein the circuit carrying and controlling module further includes:
another circuit substrate structure including another carrier substrate, another circuit layout layer disposed on the another carrier substrate, and another plurality of conductive penetration bodies that electrically connect to the another circuit layout layer and penetrate through the another carrier substrate; and
another control substrate structure including another circuit substrate disposed under the another carrier substrate, and another circuit control chip disposed on the another circuit substrate;
wherein the image display module is electrically connected to the another circuit layout layer of the another circuit substrate structure.

16. The image display according to claim 15, wherein the circuit substrate structure and the control substrate structure are disposed inside a casing, and a lateral side of the carrier substrate is adjacent to or in contact with an inner surface of the casing, so that an unoccupied gap is formed between the lateral side of the carrier substrate and the inner surface of the casing; wherein the another circuit substrate structure and the another control substrate structure are disposed inside the casing, and a lateral side of the another carrier substrate is adjacent to or in contact with another inner surface of the casing, so that another unoccupied gap is formed between the lateral side of the another carrier substrate and the another inner surface of the casing.

17. The image display according to claim 16, wherein each of the another conductive penetration bodies includes another top soldering region and another bottom soldering region corresponding to the another top soldering region, and the another circuit layout layer and the another circuit substrate are respectively and electrically connected to the another top soldering region and the another bottom soldering region; wherein the another circuit substrate includes another plurality of conductive contacts respectively and electrically connected to the another conductive penetration bodies, and the another conductive contacts of the another circuit substrate are respectively and electrically connected to the another bottom soldering regions of the another conductive penetration bodies through another anisotropic conduction film; wherein the another circuit substrate is a rigid circuit board or a flexible circuit board, and the another circuit substrate does not pass through the another unoccupied gap.

18. The image display according to claim 12, wherein the image display module is disposed above the circuit carrying and controlling module, and the image display module is a light-emitting diode display module, an organic light-emitting diode display module, or a light crystal display module for cooperating with a backlight module that is disposed under the circuit carrying and controlling module.
